(19) United States
(12) Patent Application Publication
(10) Pub. No.: US 2025/0079253 A1
(43) Pub. Date: Mar. 6, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kento ADACHI, Tokyo (JP); Satoshi YOSHIDA, Kawasaki (JP); Tatsunori SAKANO, Tokyo (JP); Tomoaki INOKUCHI, Yokohama (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/589,630

(22) Filed: Feb. 28, 2024

(30) Foreign Application Priority Data
Sep. 4, 2023 (JP) 2023-142949

(51) Int. Cl. H01L 23/367; H01L 23/00; H01L 23/31; H01L 23/498; H01L 23/538; H01L 25/065

(52) U.S. Cl. CPC H01L 23/367; H01L 23/3107; H01L 23/49811; H01L 23/5384; H01L 23/5385; H01L 24/32; H01L 25/0655; H01L 2224/32245

(57) ABSTRACT

An embodiment includes a first substrate, a second substrate, a first semiconductor element, a second semiconductor element and a third substrate. The third substrate is provided between the first substrate and the second substrate. The first semiconductor element is provided on the first substrate. The second semiconductor element is provided on the second substrate. The third substrate includes a first connection member and a second connection member that have thermal conductivity and penetrate through the third substrate. The first semiconductor element is thermally coupled to the first substrate and coupled through the first connection member to the second substrate. The second semiconductor element is thermally coupled to the second substrate and coupled through the second connection member to the first substrate.

### CROSS-REFERENCE TO RELATED APPLICATIONS

This application is based upon and claims the benefit of priority from Japanese Patent Application No. 2023-142949, filed on Sep. 4, 2023; the entire contents of which are incorporated herein by reference.

### FIELD

Embodiments relate to a semiconductor device.

### BACKGROUND

There is a power module (semiconductor device) that is equipped with multiple heat generating components such as power semiconductor elements. In such a power module, the multiple heat-generating components may be distributed and disposed on two substrates to improve a heat radiation property.

Further improvement in the heat radiation property in the power module leads to an improvement in a mounting density of an apparatus or a device equipped with the power module.

### BRIEF DESCRIPTION OF THE DRAWINGS

FIG. 1 is a schematic side view illustrating a power module according to an embodiment;

FIG. 2 is a schematic cross-sectional view illustrating the power module according to the embodiment;

FIG. 3A to FIG. 3C are schematic perspective views illustrating a first connection member that is a part of the power module according to the embodiment;

FIG. 4 is a schematic equivalent circuit diagram illustrating the power module according to the embodiment;

FIG. 5A is a schematic side view illustrating the power module according to the embodiment; and

FIG. 5B is a schematic side view illustrating the power module according to a comparative example.

### DETAILED DESCRIPTION

A semiconductor device according to an embodiment includes: a first substrate including a first base material that includes a first face and a second face opposite to the first face, and has thermal conductivity; a second substrate including a second base material that includes a third face facing the first face and a fourth face opposite to the third face, and has thermal conductivity; a first semiconductor element provided on the first face side; a second semiconductor element provided on the third face side; and a third substrate that is provided between the first substrate and the second substrate, and includes a third base material including a fifth face facing the first face and a sixth face opposite to the fifth face. The third substrate includes a first connection member that penetrates from the fifth face to the sixth face and has thermal conductivity, and a second connection member that penetrates from the fifth face to the sixth face, is provided apart from the first connection member, and has thermal conductivity. The first semiconductor element is thermally coupled to the first substrate and the first connection member between the first substrate and the first connection member. The second semiconductor element is thermally coupled to the second substrate and the second connection member between the second substrate and the second connection member.

Hereinafter, respective embodiments of the invention will be described with reference to the accompanying drawings.

The drawings are schematic and conceptual, and a relationship between the thickness and width of respective portions, a size ratio between the portions, and the like are not necessarily the same as real values. Even when the same portion is shown, dimensions and ratios may be shown differently depending on the drawings.

In the specification and the drawings, the same reference numeral will be given to the same elements which are described already, and detailed description will be appropriately omitted.

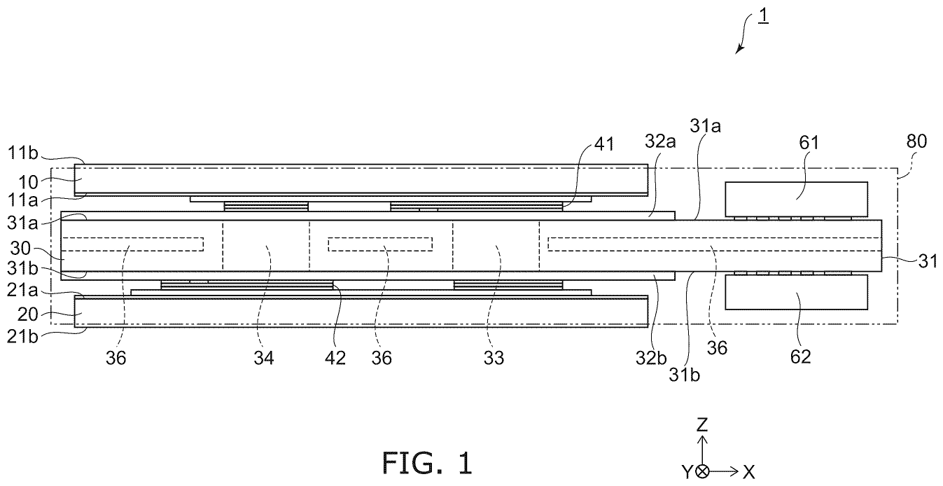

FIG. 1 is a schematic side view illustrating a power module according to a first embodiment.

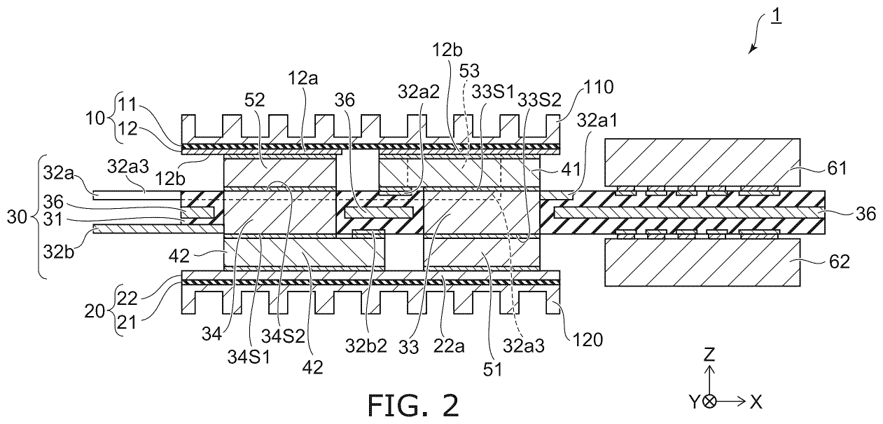

FIG. 2 is a schematic cross-sectional view illustrating the power module according to the first embodiment.

As shown in FIG. 1 and FIG. 2, a power module 1 according to the embodiment includes a first substrate 10, a second substrate 20, a third substrate 30, a first semiconductor element 41, and a second semiconductor element 42.

The first semiconductor element 41 is provided on the first substrate 10. The second semiconductor element 42 is provided on the second substrate 20. The third substrate 30 is provided between the first substrate 10 and the second substrate 20. The power module 1 includes a casing 80 that accommodates the first substrate 10, the second substrate 20, the third substrate 30, the first semiconductor element 41, and the second semiconductor element 42. The casing 80 is formed from an insulating material. The casing 80 is formed from, for example, an epoxy-based resin or the like. In FIG. 1, the casing 80 is indicated by a two-dot chain line to illustrate a mutual relationship of the first substrate 10, the second substrate 20, the third substrate 30, the first semiconductor element 41, and the second semiconductor element 42 from a side surface.

The first substrate 10 includes a base material (first base material) 11 and a wiring layer (first wiring layer) 12. The base material 11 is a plate-shaped member including a first face 11a and a second face 11b. The second face 11b is a face opposite to the first face 11a.

Hereinafter, a configuration and the like of the power module 1 will be described by using a three-dimensional coordinate system. The three-dimensional coordinate system is an XYZ coordinate system. It is assumed that the first face 11a of the base material 11 is a plane, and an XY-plane is parallel to the first face 11a. In an example in FIG. 1, the first semiconductor element 41 and the second semiconductor element 42 are arranged in an X-direction. A Z axis is orthogonal to the XY-plane, a direction from the first face 11a to the second face 11b is set as a positive direction, and the opposite direction is set as a negative direction.

In FIG. 2, lengths of some constituent elements in the Z-axis direction are exaggerated to clearly show mutual relationships of positions of the first substrate 10, the second substrate 20, the third substrate 30, a first connection member 33, a second connection member 34, the first semiconductor element 41, and the second semiconductor element 42. In addition, each constituent element is shown as a single constituent member even though the constituent element is composed of multiple constituent members in order to avoid complication of illustration in the drawing. Hereinafter, a length in the Z-axis direction may be referred to as a thickness or a height.

The base material 11 has an insulating property at least on the first face 11a. The base material 11 is formed from a material having high thermal conductivity. The base material 11 contains, for example, Al₂O₃, AlN, or the like. The base material 11 may contain a metal such as Cu and Al.

The wiring layer 12 is provided on the first face 11a. The wiring layer 12 may include multiple wirings. The multiple wirings may be electrically connected to each other or electrically isolated from each other. In the specific example in FIG. 2, the wiring layer 12 includes wirings 12a and 12b. The wiring 12a is electrically connected to a fourth connection member 52. The wiring 12b is electrically connected to the first semiconductor element 41. In the example, the wiring 12a is electrically isolated from the wiring 12b.

The second substrate 20 includes a base material (second base material) 21, and a wiring layer (second wiring layer) 22. The base material 21 is a plate-shaped member including a third face 21a and a fourth face 21b. The fourth face 21b is a face opposite to the third face 21a. The first substrate 10 and the second substrate 20 are disposed so that from the first face 11a to the fourth face 21b are approximately parallel to each other. The second substrate 20 is disposed at a position where the third face 21a faces the first face 11a.

The base material 21 has an insulating property at least on the third face 21a. The base material 21 is formed from a material having high thermal conductivity. The base material 21 contains, for example, Al₂O₃ and AlN. The base material 21 may contain a metal such as Cu and Al. The base materials 11 and 21 may be formed from the same material or different materials.

The wiring layer 22 may include multiple wirings. The multiple wirings may be electrically connected to each other or electrically isolated from each other. In the example in FIG. 2, the wiring layer 22 includes a wiring 22a. The wiring 22a is electrically connected to a third connection member 51 and the second semiconductor element 42, respectively. Although not illustrated in FIG. 2, the wiring layer 22 may include another wiring that is electrically isolated from, for example, the wiring 22a.

The first semiconductor element 41 is electrically connected to the wiring layer 12. The second semiconductor element 42 is electrically connected to the wiring layer 22. For example, the first semiconductor element 41 and the second semiconductor element 42 are power semiconductor elements such as an insulated gate bipolar transistor (IGBT), a metal oxide semiconductor field effect transistor (MOSFET), a gate turn-off thyristor (GTO), and a diode. The power semiconductor element contains Si, SiC, GaN, or the like. The first semiconductor element 41 and the second semiconductor element 42 may be the same type of power semiconductor elements or may be different type of power semiconductor elements.

The first semiconductor element 41 is provided between the first substrate 10 and the third substrate 30, and the second semiconductor element 42 is provided between the third substrate 30 and the second substrate 20. The first semiconductor element 41 and the second semiconductor element 42 are disposed apart from each other in an X-axis direction.

The third substrate 30 includes a base material 31, the first connection member 33, and the second connection member 34. The base material 31 is a plate-shaped member including a fifth face 31a and a sixth face 31b. The sixth face 31b is a face located on a side opposite to the fifth face 31a. The fifth face 31a and the sixth face 31b are disposed to be approximately parallel to the first face 11a. The fifth face 31a faces the first face 11a and the sixth face 31b faces the third face 21a.

The base material 31 is formed from a material having an insulating property. The base material 31 is formed from, for example, a glass epoxy substrate material such as FR-4, a glass composite substrate material such as CEM-3, or the like.

The first connection member 33 and the second connection member 34 are provided to penetrate from the fifth face 31a to the sixth face 31b.

The first connection member 33 includes a mounting face 33S1 and a heat radiation face 3352. The mounting face 33S1 is exposed from the base material 31 on the fifth face 31a side. The heat radiation face 33S2 is exposed from the base material 31 on the sixth face 31b side.

The second connection member 34 includes a mounting face 34S1 and a heat radiation face 34S2. The mounting face 34S1 is exposed from the base material 31 on the sixth face 31b side. The heat radiation face 34S2 is exposed from the base material 31 on the fifth face 31a side.

In a specific example in FIG. 2, the third connection member 51 is provided between the heat radiation face 33S2 and the wiring layer 22. The third connection member 51 thermally couples the first connection member 33 and the wiring layer 22. The third connection member 51 has a function as a spacer that adjusts a length between the third substrate 30 and the second substrate 20 in the Z-axis direction. For example, the thickness of the third connection member 51 is equal to the thickness of the second semiconductor element 42.

The fourth connection member 52 is provided between the heat radiation face 3452 and the wiring layer 12. The fourth connection member 52 thermally couples the second connection member 34 and the wiring layer 12. The fourth connection member 52 has a function as a spacer that adjusts a length between the third substrate 30 and the first substrate 10 in the Z-axis direction. For example, the thickness of the fourth connection member 52 is equal to the thickness of the first semiconductor element 41.

The first semiconductor element 41 is provided between the first substrate 10 and the first connection member 33. The first semiconductor element 41 is thermally coupled to the first substrate 10. In addition, the first semiconductor element 41 is thermally coupled to the first connection member 33 on the mounting face 33S1. The first connection member 33 is thermally coupled to the second substrate 20 on the heat radiation face 33S2 through the third connection member 51.

Heat generated by the first semiconductor element 41 is radiated by the first substrate 10. In addition, heat generated by the first semiconductor element 41 is conducted to the second substrate 20 through the first connection member 33 and the third connection member 51, and is radiated by the second substrate 20.

The second semiconductor element 42 is provided between the second connection member 34 and the second substrate 20. The second semiconductor element 42 is thermally coupled to the second substrate 20. In addition, the second semiconductor element 42 is thermally coupled to the second connection member 34 on the mounting face 34S1. The second connection member 34 is thermally coupled to the first substrate 10 on the heat radiation face 3452 through the fourth connection member 52.

Heat generated by the second semiconductor element 42 is radiated by the second substrate 20. In addition, heat generated by the second semiconductor element 42 is conducted to the first substrate 10 through the second connection member 34 and the fourth connection member 52, and is radiated by the first substrate 10.

The first connection member 33, the second connection member 34, the third connection member 51, and the fourth connection member 52 are formed from a material having high thermal conductivity. Thermal conductivity of the first connection member 33, the second connection member 34, the third connection member 51, and the fourth connection member 52 is sufficiently higher than thermal conductivity of the base material 31.

In the heat generated by the first semiconductor element 41, the majority of heat that is conducted through the first connection member 33 and the third connection member 51 is conducted to the second substrate 20 side. In the heat generated by the second semiconductor element 42, the majority of heat that is conducted through the second connection member 34 and the fourth connection member 52 is conducted to the first substrate 10 side. Since the first semiconductor element 41 and the second semiconductor element 42 are disposed apart from each other in an X-axis direction, the heat generation of the first semiconductor element 41 and the heat generation of the second semiconductor element 42 are radiated after being conducted through different routes. Therefore, in the power module 1, a high heat radiation property is realized.

As shown in FIG. 2, a first heat sink 110 can be provided on the second face 11b. The first substrate 10 is thermally coupled to the first heat sink 110. Favorably, a second heat sink 120 is also provided on the fourth face 21b. The first heat sink 110 and the second heat sink 120 have thermal resistance sufficiently lower than that of the first base material 11 and the second base material 21. Therefore, heat generated by the first semiconductor element 41 is more efficiently radiated by the first heat sink 110 and the second heat sink 120. Heat generated by the second semiconductor element 42 is more efficiently radiated by the first heat sink 110 and the second heat sink 120.

The first heat sink 110 and the second heat sink 120 may be an air-cooling heat sink or a water-cooling heat sink. In a case of providing the air-cooling heat sink, only one of the heat sinks may be provided, or both the heat sinks may be provided in correspondence with convection or the like due to arrangement of the power module 1.

Circuit components 61 and 62 are provided on the third substrate 30. In the example in FIG. 1 and FIG. 2, the circuit component 61 is provided on the fifth face 31a side, and the circuit component 62 is provided on the sixth face 31b side. The circuit components 61 and 62 are, for example, passive components such as a capacitor and a resistive element, functional modules including an integrated circuit and various sensors, or the like, and an input/output current is smaller and an amplitude of an input/output voltage is lower as compared with the first semiconductor element 41 and the second semiconductor element 42. In addition, heat generation of the circuit components 61 and 62 is smaller than heat generation of the first semiconductor element 41 and the second semiconductor element 42. For example, the circuit components 61 and 62 are circuit elements that drive the first semiconductor element 41 and the second semiconductor element 42, or that control a circuit that drives the first semiconductor element 41 and the second semiconductor element 42.

The third substrate 30 includes a conductive layer 36 provided in an inner layer of the base material 31. The conductive layer 36 is provided between the fifth face 31a and the sixth face 31b. In the specific example, the conductive layer 36 is electrically isolated from the first connection member 33 and the second connection member 34. The conductive layer 36 is also provided between the circuit component 61 and the circuit component 62. For example, a ground potential is applied to the conductive layer 36. For example, the conductive layer 36 functions as a shielding layer against electromagnetic radiation caused by a switching operation of the first semiconductor element 41 and the second semiconductor element 42, or the like.

Since the circuit components 61 and 62 are provided on the conductive layer 36 functioning as the shielding layer, malfunction due to the electromagnetic radiation or the like can be suppressed.

The third substrate 30 includes a wiring layer (third wiring layer) 32a. The wiring layer 32a is provided on the fifth face 31a side. The wiring layer 32a can include multiple wirings 32a1, 32a2, and 32a3. The multiple wirings 32a1, 32a2, and 32a3 may be electrically connected to each other or electrically isolated from each other.

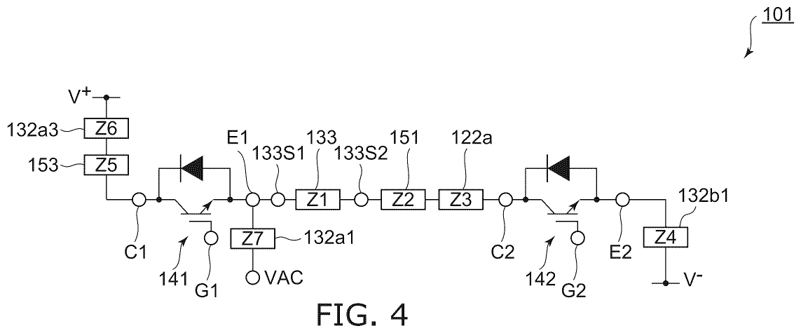

In the wiring layer 32a, the thicknesses of the wirings 32a1, 32a2, and 32a3 can be made different from each other. The thickness of the wirings 32a1 and 32a3 is large. The thickness of the wiring 32a2 is smaller than the thickness of the wirings 32a1 and 32a3. The wiring 32a1 having a large thickness is electrically connected to, for example, a main electrode of the first semiconductor element 41. The main electrode is, for example, an emitter electrode of the IGBT. The wiring 32a1 can be used as a lead wire for connecting the emitter electrode of the first semiconductor element 41 to an external circuit. As to be described later with reference to FIG. 4, in a case where the power module 1 is configured as a half-bridge circuit 101, when the wiring 32a1 is set as a lead wire, the wiring 32a1 can also be set as a terminal for taking out a neutral point potential (AC output voltage) VAC.

The wiring 32a3 having a large thickness is electrically connected to the wiring 12b through a fifth connection member 53. The fifth connection member 53 is disposed between the wiring 32a3 and the wiring 12b on a positive side of the first semiconductor element 41 in a Y-direction, and electrically connects the wiring 32a3 and the wiring 12b. The thickness of the fifth connection member 53 is equal to the thickness of the first semiconductor element 41 and the thickness of the fourth connection member 52, and also functions as a spacer. As in the specific example in FIG. 2, the wiring 32a3 may be drawn out as a lead wire for connection with an external circuit. In this case, the wiring 32a3 can also be used as a terminal for connection of a DC power source V⁺ of the half-bridge circuit 101 to be described later with reference to FIG. 4.

As described above, when the thickness of the wirings 32a1 and 32a3 is made large, a large current can be allowed to flow through the wirings 32a1 and 32a3.

For example, the wiring 32a2 having a small thickness electrically connects a control electrode of the first semiconductor element 41 and the circuit component 61. The control electrode is, for example, a gate electrode of the IGBT. A current that is sufficiently smaller than the current flowing through the wirings 32a1 and 32a3 can be allowed to flow through the wiring 32a2.

The third substrate 30 includes a wiring layer (fourth wiring layer) 32b. The wiring layer 32b is provided on the sixth face 31b side. The wiring layer 32b can include multiple wirings 32b1 and 32b2. The multiple wirings 32b1 and 32b2 may be electrically connected to each other or electrically isolated from each other.

In the wiring layer 32b, the thicknesses of the wirings 32b1 and 32b2 may be made different from each other. The thickness of the wiring 32b1 is large. The thickness of the wiring 32b2 is smaller than the thickness of the wiring 32b1.

For example, the wiring 32b1 having a large thickness is electrically connected to, for example, a main electrode of the second semiconductor element 42. The main electrode is, for example, an emitter electrode of the IGBT. A large current can be allowed to flow through the wiring 32b1. As in the specific example in FIG. 2, the wiring 32b1 can also be used as a lead wire for connection with an external circuit. In a case where the power module 1 is configured as the half-bridge circuit 101 as to be described later with reference to FIG. 4, the wiring 32b1 can also be used as a terminal for connection of a DC voltage source V⁻.

For example, the wiring 32b2 having a small thickness is electrically connected to a control electrode of the second semiconductor element 42. The control electrode is, for example, a gate electrode of the IGBT. A current sufficiently smaller than a current flowing through the wiring 32b1 can be allowed to be flow through the wiring 32b2.

When the wiring layers 32a and 32b include wirings having different thicknesses, a wiring having a large thickness is applicable to a route through which a large current flows, and a wiring having a small thickness is applicable to a route through which a small current flows. In a case where the wiring having a large thickness is applied to the route through which the large current flows, it is not necessary to increase the length of the wiring in the X-direction and the Y-direction. In a case where the wiring having a small thickness is applied to the route through which the small current flows, it is easy to set a wiring interval to be narrow. According to these, it is possible to improve an arrangement density of circuit elements arranged on the third substrate 30.

Favorably, the first connection member 33, the second connection member 34, the third connection member 51, and the fourth connection member 52 are formed from an electrically conductive material. The first connection member 33, the second connection member 34, the third connection member 51, and the fourth connection member 52 are formed from, for example, a metal material such as Cu, Al, an alloy containing these metals, or the like.

According to this, as to be described later with reference to FIG. 4, in the third substrate 30, the first connection member 33 can electrically connect the first semiconductor element 41 to the wiring layer 22 of the second substrate 20, and the second connection member 34 can electrically connect the second semiconductor element 42 to the wiring layer 12 of the first substrate 10. In addition, the first connection member 33 and the second connection member 34 can also be electrically connected to the wiring layers 32a and 32b, and the conductive layer 36 provided on the third substrate 30.

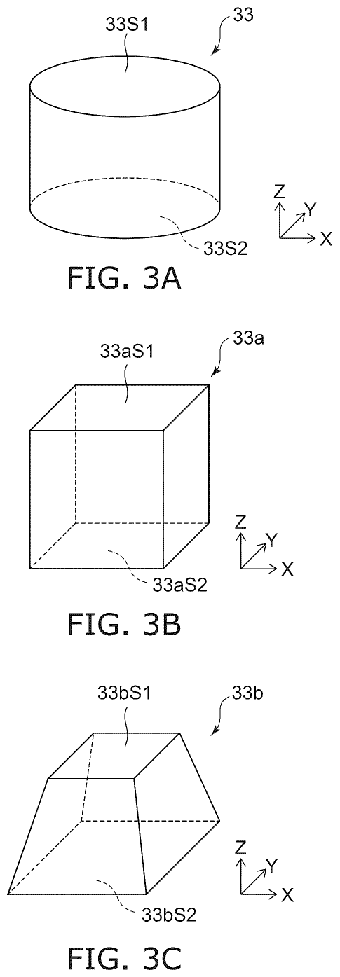

FIG. 3A to FIG. 3C are schematic perspective views illustrating the first connection member that is a part of the power module according to the embodiment.

As shown in FIG. 3A, the first connection member 33 can be set to a circular column shape. In the first connection member 33, the mounting face 33S1 and the heat radiation face 33S2 have a circular shape in XY-plan view. It is favorable that an area of the mounting face 3351 and the heat radiation face 33S2 is sufficiently large. For example, when the area of the mounting face 33S1 and the heat radiation face 33S2 is set to be approximately equal to or larger than an area of a main electrode to be connected to the mounting face 33S1 of the first semiconductor element 41 in the XY-plan view, thermal resistance due to connection between the first semiconductor element 41 and the first connection member 33 can be reduced, and the heat radiation property of the first semiconductor element 41 can be improved.

The first connection member 33 is not limited to the circular column shape, and may be set to, for example, an elliptical column shape in correspondence with an outer peripheral shape of the first semiconductor element 41 in the XY-plan view.

As shown in FIG. 3B, a first connection member 33a may be set to a square column shape. In the first connection member 33a, a mounting face 33aS1 and a heat radiation face 33aS2 have a rectangular shape. When the area of the mounting face 33aS1 and the heat radiation face 33aS2 is set to be approximately equal to or larger than an area of the main electrode to be connected to the mounting face 33S1 of the first semiconductor element 41 in the XY-plan view, thermal resistance due to connection between the first semiconductor element 41 and the first connection member 33a can be reduced, and the heat radiation property of the first semiconductor element 41 can be improved.

In addition, the shape of the outer periphery of the mounting face 33aS1 and the heat radiation face 33aS2 may be set so that the outer periphery of the mounting face 33aS1 and the heat radiation face 33aS2 overlaps the outer periphery of the main electrode of the first semiconductor element 41 to be connected to the mounting face 33S1 in the XY-plan view, or is positioned on an outer side of the outer periphery of the main electrode of the first semiconductor element 41 to be connected to the mounting face 33S1 in the XY-plan view. In this case, thermal coupling between the first semiconductor element 41 and the first connection member 33a can be strengthened, and the heat radiation property of the first semiconductor element 41 can be further improved.

In addition, when the shape of the mounting face 33aS1 and the heat radiation face 33aS2 is set to the rectangular shape, an arrangement density of respective wirings of the wiring layers 32a and 32b can be improved.

As shown in FIG. 3C, a first connection member 33b may be set to a truncated square pyramid shape. A mounting face 33bS1 and a heat radiation face 33bS2 have a rectangular shape. In the specific example, an area of the heat radiation face 33bS2 is larger than an area of the mounting face 33bS1. In this case, it is possible to realize a sufficiently high heat radiation property by reducing thermal resistance on the second substrate 20 side while improving a wiring density in the third substrate 30.

The first connection member 33b may be set to, for example, a truncated cone, a truncated elliptical cone, or the like without limitation to the truncated square pyramid in correspondence with the outer peripheral shape of the first semiconductor element 41 in the XY-plan view.

In the above description, the shape of the first connection member 33 has been described, but the shape of the second connection member 34 can be set in a similar manner. In addition, the shape of the first connection members 33, 33a, and 33b is illustrative only, and an appropriate shape can be set in any manner in correspondence with arrangement of respective wirings of the wiring layers on the third substrate 30, the size of a semiconductor element, the shape of an electrode, and the like. FIG. 4 is a schematic equivalent circuit diagram of the power model according to the embodiment.

In each of the wiring layer 12 formed on the first substrate 10, and the wiring layers 12 and 22 formed on the second substrate 20, it is possible to construct a power module having a desired circuit configuration by approximately connecting the wirings.

Circuit elements in FIG. 4 correspond to constituent elements shown in FIG. 1 and FIG. 2 (hereinafter, referred to as FIG. 1 and the like). That is, a semiconductor element 141 and a semiconductor element 142 respectively correspond to the first semiconductor element 41 and the second semiconductor element 42 in FIG. 1 and the like. Connection members 133 and 151, and a wiring 122a respectively correspond to the first connection member 33, the third connection member 51, and the wiring 22a in FIG. 1 and the like. A wiring 132b1 corresponds to the wiring 32b1 in FIG. 1 and the like. A connection member 153 and a wiring 132a3 correspond to the fifth connection member 53 and the wiring 32a3 in FIG. 1 and the like. A wiring 132a1 corresponds to the wiring 32a1 in FIG. 1 and the like.

As shown in FIG. 4, for example, the power module 1 shown in FIG. 1 and the like can include the half-bridge circuit 101. The half-bridge circuit 101 is a series circuit of the semiconductor elements 141 and 142. Each of the semiconductor elements 141 and 142 is, for example, an insulated gate bipolar transistor (IGBT). Each of the semiconductor elements 141 and 142 includes a diode that is connected to the IGBT in reverse parallel.

The semiconductor element 141 includes a collector electrode C1, an emitter electrode E1, and a gate electrode G1. The collector electrode C1 is electrically connected to a DC voltage source V⁺ through the connection member 153 and the wiring 132a3. The emitter electrode E1 is electrically connected to the connection member 133 on a mounting face 133S1. The connection member 133 is electrically connected to the connection member 151 on a heat radiation face 13352, and is electrically connected to the wiring 122a. The emitter electrode E1 is electrically connected to one end of the wiring 132a1, and a neutral point potential VAC is output from the other end of the wiring 132a1.

The semiconductor element 142 includes a collector electrode C2, an emitter electrode E2, and a gate electrode G2. The collector electrode C2 is electrically connected to the wiring 122a. The emitter electrode E2 is electrically connected to a DC voltage source V-through the wiring 132b1. A voltage value of the DC voltage source V⁺ is higher than a voltage value of the DC voltage source V.

The connection members 133 and 151 and the wiring 122a have impedance Z1, impedance Z2, and impedance Z3, respectively. The wiring 132b1 has impedance Z4. The connection member 153 and the wiring 132a3 have impedance Z5 and impedance Z6, respectively. The wiring 132a1 has impedance Z7. That is, impedance of the first connection member 33, impedance of the third connection member 51, and impedance of the wiring 22a correspond to the impedance Z1, the impedance Z2, and the impedance Z3, respectively. Impedance of the wiring 32b1 corresponds to the impedance Z4. Impedance of the fifth connection member 53 and impedance of the wiring 32a3 correspond to the impedance Z5 and the impedance Z6, respectively. Impedance of the wiring 32a1 corresponds to the impedance Z7.

The area of the mounting face 33S1 and the heat radiation face 33S2 of the first connection member 33 can be set to be sufficiently large. The area of the third connection member 51 and the wiring 22a in the XY-plan view can be set to be sufficiently large. The area of the wiring 32b1 in the XY-plan view can be set to be sufficiently large. The area of the fifth connection member 53 and the wiring 32a3 in the XY-plan view can be set to be sufficiently large. The area of the wiring 32a1 in the XY-plan view can be set to be sufficiently large.

The first connection member 33, the third connection member 51, the wiring 22a, the wiring 32b1, the fifth connection member 53, the wiring 32a3, and the wiring 32a1 can be formed from a metal material such as Cu. Therefore, when these are set to the above-described shape, a DC resistance value corresponding to each of the impedance Z1, the impedance Z2, the impedance Z3, the impedance Z4, the impedance Z5, the impedance Z6, and the impedance Z7 can be sufficiently lowered.

In addition, a parasitic inductance value corresponding to each of the impedance Z1, the impedance Z2, the impedance Z3, the impedance Z4, the impedance Z5, the impedance Z6, and the impedance Z7 can also be sufficiently small according to the above-described shape.

When the DC resistance value corresponding to each of the impedance Z1, the impedance Z2, the impedance Z3, the impedance Z4, the impedance Z5, the impedance Z6, and the impedance Z7 is set to be sufficiently small, a loss occurred in the DC resistance can be reduced. In addition, since a voltage drop caused by the DC resistance can be suppressed, for example, it is possible to sufficiently secure the magnitude of a voltage that is applied to the control electrode of the semiconductor element.

Since the parasitic inductance value corresponding to each of the impedance Z1, the impedance Z2, the impedance Z3, the impedance Z4, the impedance Z5, the impedance Z6, and the impedance Z7 is made sufficiently small, it is possible to suppress occurrence of a noise or a surge voltage associated with the high-speed switching operation of the semiconductor element.

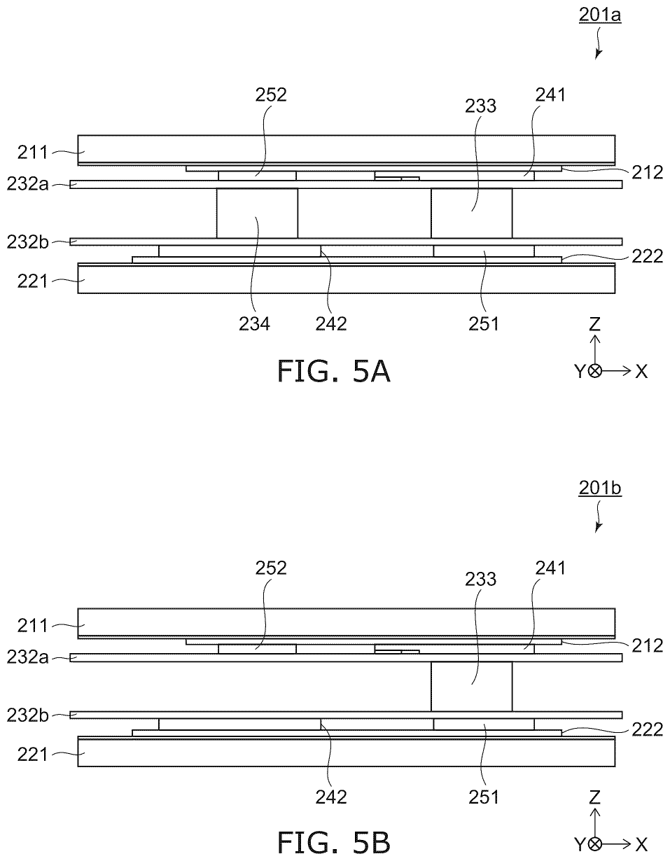

FIG. 5A is a schematic side view illustrating the power module according to the embodiment. FIG. 5B is a schematic side view illustrating a power module according to a comparative example.

FIG. 5A shows a model 201a for performing thermal simulation in the configuration of the power module 1 shown in FIG. 1 and the like.

In the model 201a in FIG. 5A, semiconductor elements 241 and 242 correspond to the first semiconductor element 41 and the second semiconductor element 42 shown in FIG. 1 and the like, respectively. A base material 211 and a wiring layer 212 correspond to the base material 11 and the wiring layer 12 shown in FIG. 1 and the like, respectively. A base material 221 and a wiring layer 222 correspond to the base material 21 and the wiring layer 22 shown in FIG. 1 and the like, respectively. Connection members 233, 234, 251, and 252 correspond to the first connection member 33, the second connection member 34, the third connection member 51, and the fourth connection member 52 shown in FIG. 1 and the like, respectively. Wiring layers 232a and 232b correspond to the wiring layers 32a and 32b shown in FIG. 1 and the like, respectively.

FIG. 5B shows a model 201b in which the connection member 234 is excluded from the model 201a in FIG. 5A. In the models 201a and 201b, notation of a model element corresponding to the base material 31 of the third substrate 30 shown in FIG. 1 and the like is omitted to avoid complication of illustration in the drawing and to clearly show the configuration of the connection members 233 and 234. In simulation using the models 201a and 201b, model elements corresponding to the material and the shape of the base material 31 are provided.

In the models 201a and 201b, model elements are set to an appropriate material and an appropriate shape, and a power loss of 1 W is applied to a model element of the semiconductor element 241, and a heat transfer coefficient corresponding to forced cooling by water flow is applied to model elements of the base materials 211 and 221.

Under the conditions, in the model 201a corresponding to the power module 1 according to the embodiment, it is confirmed that thermal resistance of approximately 40% is reduced as compared with the model 201b of the comparative example.

An effect of the power module 1 according to the embodiment will be described.

The power module 1 according to the embodiment includes the first substrate 10, the second substrate 20, the third substrate 30, the first semiconductor element 41, and the second semiconductor element 42. The third substrate 30 is provided between the first semiconductor element 41 provided on the first substrate 10, and the second semiconductor element 42 provided on the second substrate 20. The third substrate includes the first connection member 33 and the second connection member 34 which penetrate through the base material 31.

The first connection member 33 and the second connection member 34 have high thermal conductivity. In addition, the base material 11 of the first substrate 10 and the base material 21 of the second substrate 20 have high thermal conductivity.

The first connection member 33 is thermally coupled to the first semiconductor element 41 on the mounting face 33S1, and is thermally coupled to the second substrate 20 on the heat radiation face 3352 through the third connection member 51. Therefore, heat of the first semiconductor element 41 is radiated by the first substrate 10, and is radiated by the second substrate 20 through the first connection member 33 and the third connection member 51.

The second connection member 34 is thermally coupled to the second semiconductor element 42 on the mounting face 34S1, and is thermally coupled to the first substrate 10 on the heat radiation face 3452 through the fourth connection member 52. Therefore, heat of the second semiconductor element 42 is radiated by the second substrate 20, and is radiated by the first substrate 10 through the second connection member 34 and the fourth connection member 52.

That is, it is possible to radiate heat of the first semiconductor element 41 from both the first substrate 10 side and the second substrate 20 side by the first connection member 33 and the second connection member 34 provided to penetrate through the base material 31 of the third substrate 30. Similarly, it is possible to radiate heat of the second semiconductor element 42 from both the first substrate 10 side and the second substrate 20 side. Therefore, the power module 1 according to the embodiment realizes high heat radiation performance.

In the first connection member 33, the area of the mounting face 33S1 that is thermally coupled to the first semiconductor element 41 can be set to be sufficiently large, and can be set to be approximately the same as an area of a thermal coupling face of the first semiconductor element 41 with the mounting face 33S1. Therefore, contact thermal resistance between the first semiconductor element 41 and the first connection member 33 can be reduced, and the heat radiation performance of the power module 1 can be improved.

In the second connection member 34, similarly, the area of the mounting face 34S1 can be set to be sufficiently large, and can be set to be approximately the same as an area of a thermal coupling face of the second semiconductor element 42 with the mounting face 34S1. Therefore, contact thermal resistance between the second semiconductor element 42 and the second connection member 34 can be reduced, and the heat radiation performance of the power module 1 can be improved.

As illustrated in FIG. 3A to FIG. 3C, the shape of each of the first connection member 33 and the second connection member 34 can be appropriately set. According to this, the heat radiation performance of the power module 1 can be improved, and the degree of freedom of arrangement of circuit elements including the first semiconductor element 41 and the second semiconductor element 42 can be improved, or an arrangement density thereof can be improved.

For example, when the first connection member 33 and the second connection member 34 are formed from Cu, an ally containing Cu, or the like, the first connection member 33 and the second connection member 34 can realize high electrical conductivity while realizing high thermal conductivity. In the third substrate 30, the first connection member 33 and the second connection member 34 can be used as wiring members with low impedance. When using the first connection member 33 and the second connection member 34 as the wiring members in the third substrate 30, in a circuit element including the first semiconductor element 41 and the second semiconductor element 42, the power module 1 can switch a high voltage and a large current with a low noise and at a high speed.

The base material 31 of the third substrate 30 includes the conductive layer 36. The conductive layer 36 is provided in an inner layer of the base material 31, and can be electrically isolated from the first connection member and the second connection member 34. When connecting the conductive layer 36 to a specific potential, the conductive layer 36 can be used as an electron shielding layer. When the conductive layer 36 is provided in the third substrate 30, it is easy to provide the circuit components 61 and 62 which handle low-level signals on the third substrate 30.

In the third substrate 30, at least one of the fifth face 31a side and the sixth face 31b side, the wiring layers 32a and 32b can include wirings different in thickness. When the thickness of a wiring to which a low voltage is applied or through which a small current flows is made smaller than the thickness of a wiring to which a high voltage is applied or through which a large current flows, it is possible to form a minute wiring pattern. Therefore, a mounting density of circuit elements in the power module 1 can be improved.

In a case where the circuit configuration in the power module 1 is set as the half-bridge circuit 101 shown in FIG. 4, the wirings 32a1, 32a3, and 32b1 can be used as a lead wire for connection with an external circuit. In this case, when the thickness of the wirings is set to be sufficiently large, and an area in the XY-plan view is set to be sufficiently large, electrical connection with an external circuit can be established at low resistance and low inductance.

In addition, when the wiring 32b1 is directly connected to the emitter electrode of the second semiconductor element 42, a current is allowed to flow from the second semiconductor element 42 to the DC voltage source V-without through the second connection member 34. According to this, the second connection member 34 is less susceptible to a copper loss and an iron loss due to a current in the switching operation of the second semiconductor element 42. Therefore, since the second connection member 34 is less susceptible to heat generation due to the copper loss and the iron loss, a heat radiation effect of the second semiconductor element 42 can be enhanced.

In this manner, it is possible to realize a semiconductor device in which multiple heat generation components are mounted, and which has a high heat radiation property.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first substrate including a first base material that includes a first face and a second face opposite to the first face, and has thermal conductivity;
a second substrate including a second base material that includes a third face facing the first face and a fourth face opposite to the third face, and has thermal conductivity;
a first semiconductor element provided on the first face side;
a second semiconductor element provided on the third face side; and
a third substrate that is provided between the first substrate and the second substrate, and includes a third base material including a fifth face facing the first face and a sixth face opposite to the fifth face,
the third substrate including,
a first connection member that penetrates from the fifth face to the sixth face and has thermal conductivity, and
a second connection member that penetrates from the fifth face to the sixth face, is provided apart from the first connection member, and has thermal conductivity,
the first semiconductor element being thermally coupled to the first substrate and the first connection member between the first substrate and the first connection member, and
the second semiconductor element being thermally coupled to the second substrate and the second connection member between the second substrate and the second connection member.

2. The device according to claim 1,
wherein each of the first connection member and the second connection member has a shape selected among a circular column, an elliptical column, a square column, and a truncated pyramid shape.

3. The device according to claim 1, further comprising:
a first heat sink that is provided on the second face side and is thermally coupled to the first substrate.

4. The device according to claim 3, further comprising:
a second heat sink that is provided on the fourth face side, and is thermally coupled to the second substrate.

5. The device according to claim 1,
wherein each of the first connection member and the second connection member is electrically conductive,
the first substrate includes a first wiring layer on the first face,
the second substrate includes a second wiring layer on the third face,
the first semiconductor element is electrically connected to the first wiring layer on the first face side, and is electrically connected to the first connection member on the fifth face side, and
the second semiconductor element is electrically connected to the second wiring layer on the third face side, and is electrically connected to the second connection member on the sixth face side.

6. The device according to claim 5,
wherein the third substrate includes a third wiring layer provided on the fifth face, a fourth wiring layer provided on the sixth face, and a conductive layer provided in an inner layer of the base material,
the third substrate further includes,
a first circuit component that is provided on the fifth face side and is electrically connected to the third wiring layer, and
a second circuit component that is provided on the sixth face side and is electrically connected to the fourth wiring layer, and
the conductive layer is provided between the first circuit component and the second circuit component.

7. The device according to claim 6,
wherein the first semiconductor element includes a plurality of main electrodes, and a first control electrode,
the first circuit component is electrically connected to the first control electrode,
the second semiconductor element includes a plurality of main electrodes and a second control electrode, and
the second circuit component is electrically connected to the second control electrode.

8. The device according to claim 7,
wherein the third wiring layer includes a first wiring having a first thickness, and a second wiring having a second thickness smaller than the first thickness,
the fourth wiring layer includes a third wiring having a third thickness, and a fourth wiring having a fourth thickness smaller than the third thickness,
the second wiring electrically connects the first circuit component and the first control electrode, and
the fourth wiring electrically connects the second circuit component and the second control electrode.

9. The device according to claim 7,
wherein one main electrode of the first semiconductor element is electrically connected to the first wiring layer,
another one main electrode of the first semiconductor element is electrically connected to the first connection member,
one main electrode of the second semiconductor element is electrically connected to the second wiring layer, and
another one main electrode of the second semiconductor element is electrically connected to the second connection member.

10. The device according to claim 9,
wherein in the first wiring layer, the one main electrode of the first semiconductor element and the other one main electrode of the second semiconductor element are connected to a plurality of electrically isolated wirings.

11. The device according to claim 1,
wherein the first connection member includes a first mounting face that is thermally coupled to the first semiconductor element, and
an area of the first mounting face in plan view is equal to or larger than an area of a main electrode on a face opposed to the first mounting face in the first semiconductor element.

12. The device according to claim 11,
wherein the second connection member includes a second mounting face that is thermally coupled to the second semiconductor element, and
an area of the second mounting face in plan view is equal to or larger than an area of a main electrode on a face opposed to the second mounting face in the second semiconductor element.

13. The device according to claim 1,
wherein the first connection member and the second connection member contain Cu or Al.

14. The device according to claim 1,
wherein the first semiconductor element is one among an IGBT, a MOSFET, a GTO, and a diode, and
the second semiconductor element is one among an IGBT, a MOSFET, a GTO, and a diode.

15. The device according to claim 14,
wherein the first semiconductor element contains any one among Si, SiC, and GaN, and
the second semiconductor element contains any one among Si, SiC, and GaN.

16. The device according to claim 1,
wherein the first base material contains any one among Al₂O₃, AlN, Cu, and Al, and
the second base material contains any one among Al₂O₃, AlN, Cu, and Al.

17. The device according to claim 1, further comprising:
a casing that accommodates the first substrate, the second substrate, the third substrate, the first semiconductor element, and the second semiconductor element.

18. The device according to claim 17,
wherein the casing contains an insulating resin.

19. The device according to claim 1,
wherein thermal conductivity of the third base material is lower than any of the thermal conductivity of the first connection member and the thermal conductivity of the second connection member.

20. The device according to claim 19,
wherein the third base material contains glass fiber.
